(19) United States
(12) Patent Application Publication
(10) Pub. No.: US 2022/0415717 A1
(43) Pub. Date: Dec. 29, 2022

(54) STRUCTURE FOR DETECTING/MONITORING PROCESS CHARGING DAMAGE DUE TO METAL AND ISOLATION WELL CHARGING

(71) Applicant: Taiwan Semiconductor Manufacturing Company, Ltd., Hsinchu (TW)

(72) Inventors: Hsi-Yu Kuo, Hsinchu (TW); Yu-Lin Chu, Hsinchu (TW)

(21) Appl. No.: 17/670,863

(22) Filed: Feb. 14, 2022

Related U.S. Application Data
(60) Provisional application No. 63/214,847, filed on Jun. 25, 2021.

(51) Int. Cl. H01L 21/66; G01R 19/10

(52) U.S. Cl. CPC H01L 22/14; G01R 19/10

(57) ABSTRACT

A method of detecting or monitoring process electrical charge produced during fabrication of an integrated circuit (IC) on a semiconductor wafer includes fabricating a process charge detection circuit on or in the semiconductor wafer, including: a victim isolation well, a gate oxide disposed on or in the victim isolation well, an aggressor isolation well electrically connected with the victim isolation well via the gate oxide, a victim antenna electrically connected with the victim isolation well and together with the victim isolation well defining a victim RC time constant, and an aggressor antenna electrically connected with the aggressor isolation well and together with the aggressor isolation well defining an aggressor RC time constant that is different from the victim RC time constant. Process charge is detected using the process charge detection circuit. The detecting comprises measuring an electrical parameter of the gate oxide.

This application claims the benefit of U.S. provisional application Ser. No. 63/214,847 filed Jun. 25, 2021 and titled “Novel structure to detect/monitor process charging damage by metal and well”. U.S. provisional application Ser. No. 63/214,847 filed Jun. 25, 2021 and titled “Novel structure to detect/monitor process charging damage by metal and well” is incorporated herein by reference in its entirety.

### BACKGROUND

The following relates to integrated circuit (IC) fabrication arts, IC manufacturing process monitoring arts, IC manufacturing process optimization arts, and to related arts.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 diagrammatically illustrates: (A) a wafer having a die fabricated thereon, (B) an enlarged view of the die with indications of illustrative suitable locations for a process charge detection circuit, and (C) an electrical schematic of the process charge detection circuit according to an embodiment.

FIG. 2 diagrammatically illustrates the process charge detection circuit of FIG. 1 along with a plan view of a suitable layout and a voltage-versus-time plot of voltage across the gate oxide during electrical discharge between the aggressor isolation well and the victim isolation well.

FIG. 3 diagrammatically illustrates a process charge detection circuit according to another embodiment along with a plan view of a suitable layout and a voltage-versus-time plot of voltage across the gate oxide during electrical discharge between the aggressor isolation well and the victim isolation well.

FIGS. 4-11 illustrate further process charge detection circuit embodiments with each shown by an electrical schematic (top drawing) and by a diagrammatic cross-sectional view (bottom drawing).

FIGS. 12 and 13 illustrate two embodiments of a reference circuit shown in diagrammatic cross-sectional view.

FIG. 14 diagrammatically shows an integrated circuit (IC) fabrication process including operations for fabricating a process charge detection circuit.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the following, embodiments are disclosed for detecting or monitoring process electrical charge during fabrication of an integrated circuit (IC) on a semiconductor wafer. Process charge can be produced by various processes commonly performed during IC fabrication. For example, plasma etching or plasma deposition processes utilize an electrically charged plasma, which can deposit static electrical charge onto the semiconductor wafer. If this static electrical charge discharges through a gate oxide of a field effect transistor (FET), then this can damage or destroy the FET. This phenomenon is sometimes referred to as plasma-induced damage (PID).

More particularly, an IC typically includes devices such as diodes, field effect transistors (FETs), capacitors, diodes, and/or other circuit components which are electrically interconnected. During front end-of-line (FEOL) fabrication processing, the circuit components (FETs, diodes, et cetera) are fabricated on and/or in a semiconductor wafer, such as a silicon wafer or a silicon-on-insulator (SOI) wafer in the case of silicon-based IC technologies. The silicon of the silicon or SOI wafer may in general be doped n-type or p-type. During fabrication, isolation wells are formed to electrically isolate circuit components from one another. For example, p-type wells and/or n-type wells are electrically isolated by a buried doped layer of the opposite doping type. For example, a p-type well can be electrically isolated by an underlying n-type buried layer (NBL) or deep n-well (DNW) or the like, along with shallow trench isolation (STI), local oxidation of silicon (LOCOS), high-voltage N-well (HVNW), or another lateral isolation structure. Similarly, an n-type well can be electrically isolated by an underlying p-type buried layers (PBL), deep p-well (DPW), or the like, along with STI, LOCOS, high-voltage P-well (HVPW), or the like. Various combinations of p-type wells, n-type wells, NBLs, DNWs PBLs, DPWs, STI, LOCOS, HVNW, HVPW, and/or the like define electrical isolation wells of the IC-under-fabrication within which devices or sub-circuits are fabricated.

The FEOL processing is followed by back end-of-line (BEOL) processing, in which one or (more commonly) several metallization layers are formed, spaced apart by intervening intermetal dielectric (IMD) layers. The metallization layers are lithographically patterned to define electrically conductive paths or traces, which serve as interconnects between the various devices, connections to IC power supply lines (VDD, VSS), and/or to IC-level signal input or output lines. Electrical vias of conductive material are also formed to provide electrical connections to and/or between the lithographically defined paths or traces. The BEOL processing also typically includes forming top electrical contact pads for enabling electrical connection to and from outside the IC using wire bonding, flip-chip bonding to solder bumps, or the like. These contact pads usually include power supply pads (e.g., V_{DD} and V_{SS} contact pads in FET technologies) and signal input and/or output contact pads.

Process charge damage to circuit components is a substantial concern during IC fabrication, and the fabrication process should be designed to avoid process charge damage to sensitive components, especially the thin gate oxide of FETs. One common mechanism of process charge damage is PID channeled from an area of metallization through a FET gate. In this damage modality, the area of metallization serves as an inadvertent metal antenna to collect static electrical charge. When that metal area is electrically connected to a FET gate, for example during formation of a via connecting the metal to the gate contact, then the static charge on the metal can discharge through the gate, thus damaging or destroying the gate and hence the corresponding FET.

A process charge detection circuit for detecting such a problem can comprise a metal area connected to the gate oxide of a FET. By monitoring the voltage across the gate oxide during or after fabrication process steps, oxide gate damage can be detected.

However, there is another mode of process charge damage. This mode is based on the possibility that an isolation well can also collect static electrical charge. When two isolation wells are electrically interconnected during the BEOL metallization processing, charge can transfer via the electrical connection from a charged isolation well to a differently charged isolation well. Since the electrical interconnection is often to a gate oxide of a transistor, this can lead to gate oxide damage or destruction.

More particularly, during the IC fabrication process isolation wells can trap static electrical charge. Static electrical charge can be delivered to an isolation well of the IC-under-fabrication by various mechanisms. For example, many processes such as some types of deposition, photolithography, etching, and so forth are carried out with the wafer placed in a vacuum chamber or other chamber with a controlled ambient that is electrically insulating. In this environment, any static electric charge delivered to the wafer by the deposited material, or by plasma in a plasma etching process, or so forth, can collect in the electrical isolation wells. Even processes forming the isolation structures can introduce static charge. For example, ion implantation processes for forming a buried n-type or p-type layer to provide electrical isolation employs electrically charged ions that can leave residual static charge. Once trapped, the charge flow barriers that define the isolation well (e.g., NBL, PBL, DNW, DPW, STI, LOCOS, HVNW, HVPW, et cetera) undesirably impede or block dissipation of the accumulated static electrical charge from the isolation well.

During the subsequent BEOL processing, devices and/or sub-circuits that were fabricated in the electrical isolation wells during FEOL processing are electrically interconnected by electrically conductive traces. Such electrical interconnections enable proper operation of the final fabricated IC, and are not a problem in the final fabricated IC when it is used within its design-basis operational and environmental envelopes because the circuit-level IC design provides for static charge dissipation. For example, the V_{SS} terminal(s) of a FET-technology IC provide paths to electrical ground that can dissipate static electrical charge that might build up in an electrical isolation well. However, during the BEOL processing, the interconnection of components and sub-circuits is not yet complete, and the IC is not connected to a power supply. This can result in a situation during the BEOL processing in which one isolation well which has developed a large amount of static electrical charge is connected to another isolation well with a substantially lower amount of static electrical charge. When the interconnection is made this static electrical charge can produce a transient electrical current (referred to as an electrostatic discharge) flowing from the electrical isolation well with higher static electrical charge (the “aggressor” region) to the electrical isolation well with lower electrical charge (the “victim” region). The electrostatic discharge can produce a high enough transient electrical current to damage devices or sub-circuits carrying the transient electrical current. Such well discharge damage is especially likely to occur when isolation wells of significantly different area are electrically connected during BEOL processing, since the larger-area isolation well can accumulate a larger amount of static electrical electricity compared with the smaller-area isolation well.

A process charge detection circuit comprising a metal area connected to the gate oxide of a FET can detect oxide gate damage caused by static electrical discharge from a metallization layer to an isolation well. However, such a process charge detection circuit cannot detect situations in which static charge built up in one isolation well discharges into another isolation well during the BEOL metallization.

Disclosed herein are process charge detection circuit embodiments that are capable of detecting process charge capable of producing damage to sensitive circuit components such as FETs, regardless of whether the process charge is plasma induced damage flowing from a charged metal layer to a “victim” isolation well or is plasma induced damage flowing from an “aggressor” isolation well to a “victim” isolation well.

With reference now to the drawings, some illustrative embodiments are described.

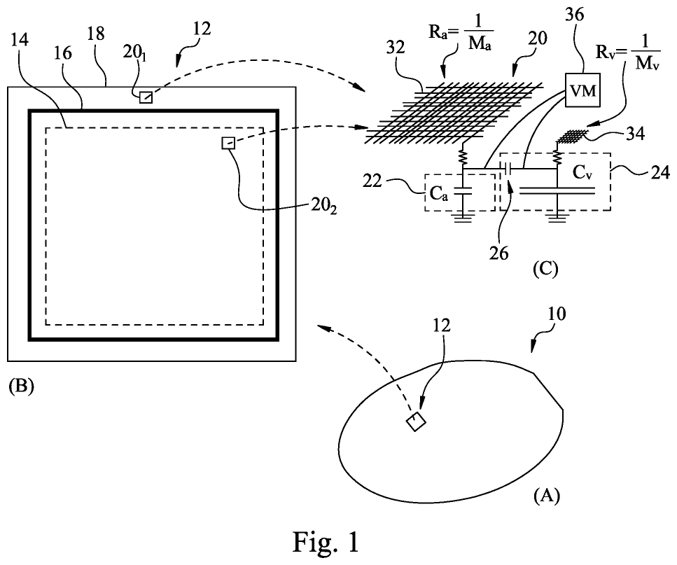

With reference to FIG. 1, part (A), a semiconductor wafer 10 is shown, which may for example be a silicon wafer, a silicon-on-insulator (SOI) wafer, or so forth. An illustrative integrated circuit (IC) die 12 (also referred to herein as an IC 12 or as a die 12) is formed on and/or in the semiconductor wafer 10. While a single die 12 is shown, more typically a two-dimensional (e.g. square or rectangular) array of dice are formed on the semiconductor wafer. Moreover, the illustrative IC die 12 may be an IC under fabrication. FIG. 1, part (B) illustrates a diagrammatic plan view of the IC 12, which includes a device area 14 in which functional circuit components are fabricated, an optional sealing ring 16 encircling the device area 14, and a street-line 18 outside the device area 14 and outside the sealing ring 16. The circuit components are formed in the device area 14 in the FEOL processing and are interconnected during the BEOL processing to form a functional IC such as a microprocessor, electronic memory chip, image sensor, or other type of IC. The optional sealing ring 16 may be formed along with the circuit components inside the device area 14. For example, if the device components include FinFET or gate-all-around (GAA) FET devices with raised (i.e. three dimensional or 3D) channels, then the deposition and patterning fabrication steps performed to fabricate the FinFET or GAA-FET channels can also form the sealing ring 16 as a 3D ring of the same material as the 3D channels. The sealing ring 16 serves a protective role for protecting the device area 14 from ingress of particulates or other contaminants. The street-line 18 corresponds to a dicing line along which the semiconductor wafer 10 is cut by a laser saw or the like to separate the IC die 12 after completion of the IC fabrication process. Optionally, the street-line 18 may include a coating of a metal or the like to suppress particulate formation during the dicing.

With continuing reference to FIG. 1, part (B) and with further reference to FIG. 1, part (C), a process charge detection circuit 20 is formed, for example in an area 201 indicated in part (B) between the sealing ring 16 and the street-line 18 or at a location 202 indicated in part (B) in the device area 14 in a location not occupied by functional circuitry. Other suitable locations (not indicated in part (B)) may include between sealing rings (in embodiments in which the sealing ring 16 comprises inner and outer sealing rings) or in the space between the (innermost) sealing ring and the device area 14. FIG. 1, part (C) shows an electrical schematic of the process charge detection circuit 20 according to an embodiment. Moreover, it will be appreciated that multiple instances of the process charge detection circuit 20 could be located in various of these areas in order to monitor process electrical charge at difference locations in the IC.

In general, the process charge detection circuit 20 includes a first isolation well 22 and a second isolation well 24. The first isolation well 22 is also referred to herein as an aggressor isolation well 22, and the second isolation well 24 is also referred to herein as a victim isolation well 24. In some further, more detailed nonlimiting illustrative embodiments, the first and second isolation wells 22, 24 are defined by respective n-type buried layer (NBL) or deep n-type well (DNW) well structures. However, more generally the first and second isolation wells 22, 24 can be either n-type or p-type depending on the technology family and specific IC design, and various isolation structures or combinations of isolation structures can be used to electrically isolate the first and second isolation wells 22, 24, such as NBL, DNW, shallow trench isolation (STI), local oxidation of silicon (LOCOS), high-voltage N-well (HVNW), p-type buried layer (PBL), deep p-well (DPW), or other structures. Electrically, the first (i.e. aggressor) isolation well 22 is represented by a capacitance Cₐ, and similarly the second (i.e. victim) isolation well 24 is represented by a capacitance Cᵥ. In general, the aggressor isolation well capacitance Cₐ is proportional to the area of the aggressor isolation well 22, and similarly the victim isolation well capacitance Cᵥ is proportional to the area of the victim isolation well 24. That is, the larger the area of an isolation well (for example, as measured in cm², mm², or some other area unit) the larger its capacitance. In the nonlimiting illustrative examples, the aggressor and victim isolation wells 22, 24 are defined by NBL structure, and so the area of the aggressor isolation well 22 is sometimes referred to herein as NBLₐ area, and similarly the area of the aggressor isolation well 22 is sometimes referred to herein as NBLᵥ area. Hence, Cₐ ∝ NBLₐ area and Cᵥ ∝ NBLᵥ area where “∝” denotes proportionality.

With continuing reference to FIG. 1, part (C), a gate oxide 26 is disposed on or in the victim isolation well. By “on or in” it is to be appreciated that the gate oxide 26 could be formed in the victim well 24 by, for example, thermal oxidation of a silicon surface of the victim well 24 to form the gate oxide 26, or by deposition of an oxide on the silicon surface of the victim well 24 to form the gate oxide 26, or some combination thereof. (As used herein, “on or in” encompasses “on”, “in”, or “on and in”). In the non-limiting illustrative embodiments, the gate oxide 26 is the gate oxide of a field-effect transistor (FET), such as a planar FET, a FinFET, or a GAA-FET (not shown in FIG. 1, part (C)). As seen in FIG. 1, part (C), the aggressor isolation well 22 is electrically connected with the victim isolation well 24 via the gate oxide 26.

Furthermore, a first antenna 32 (also referred to herein as an aggressor antenna 32) is electrically connected with the aggressor isolation well 22. The first (i.e. aggressor) antenna 32 typically comprises a region of a patterned metallization layer formed during the BEOL processing stage of the fabrication of the IC 12. The first (i.e. aggressor) antenna 32 has an area denoted herein as Mₐ. Electrically, the first (i.e. aggressor) antenna 32 has an effective resistance

$${R}_{a} = \frac{1}{{M}_{a}} .$$

(More precisely, the first antenna resistance Rₐ is proportional to the metal area Mₐ of the first antenna, i.e.

$${R}_{a} ∝ \frac{1}{{M}_{a}}$$

where again “∝” denotes proportionality; however, since the analyses presented herein employ ratios in which the constant of proportionality typically drops out, the equality expression is sometimes used herein for simplicity). The aggressor antenna 32 and the aggressor isolation well 22 together define an aggressor RC time constant RₐCₐ, that is, the aggressor time constant is the product of the resistance Rₐ of the first antenna 32 and the capacitance Cₐ of the first isolation well 22.

Similarly, a second antenna 34 (also referred to herein as a victim antenna 34) is electrically connected with the victim isolation well 24. The second (i.e. victim) antenna 34 typically comprises a region of a patterned metallization layer formed during the BEOL processing stage of the fabrication of the IC 12. The second (i.e. victim) antenna 34 has an area denoted herein as Mᵥ. Electrically, the second (i.e. victim) antenna 34 has an effective resistance

$${R}_{v} = \frac{1}{{M}_{v}}$$

(or

$${R}_{v} ∝ \frac{1}{{M}_{v}}$$

to be more precise).

The victim antenna 34 and the victim isolation well 24 together define a victim RC time constant RᵥCᵥ, that is, the victim time constant is the product of the resistance Rᵥ of the second antenna 34 and the capacitance Cᵥ of the second isolation well 24.

In various embodiments of the process charge detection circuit, the two isolation wells 22, 24 and their associated antennae 32, 34 are asymmetric in the sense that the aggressor RC time constant RₐCₐ is different from the victim RC time constant RᵥCᵥ. In some non-limiting embodiments, this difference is at least a factor of eight, that is, RₐCₐ is at least eight times larger than RᵥCᵥ or alternatively RᵥCᵥ is at least eight times larger than RₐCₐ, to provide a sufficiently large difference in RC time constants between the aggressor and victim to provide for a desirably gradual release of any the process charge. In some embodiments this difference is at least a factor of sixteen, that is, RₐCₐ is at least sixteen times larger than RᵥCᵥ or alternatively RᵥCᵥ is at least sixteen times larger than RₐCₐ. Asymmetry of the RC time constants can be obtained in various ways. The RC time constants can be written as

$${R}_{a} {C}_{a} ∝ \frac{{C}_{a}}{{M}_{a}} and {R}_{v} {C}_{v} ∝ \frac{{C}_{v}}{{M}_{ν}} .$$

Further substituting aggressor well NBLₐ area which is proportional to Cₐ and victim well NBLᵥ area which is proportional to Cᵥ yields

$${R}_{a} {C}_{a} ∝ \frac{N B {L}_{a} a r e a}{{M}_{a}} and {R}_{v} {C}_{v} ∝ \frac{N B {L}_{v} a r e a}{{M}_{ν}} .$$

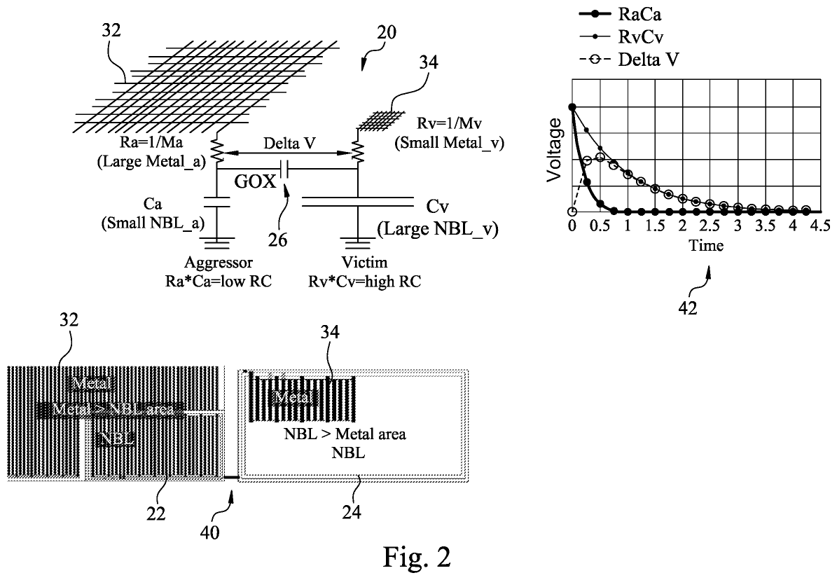

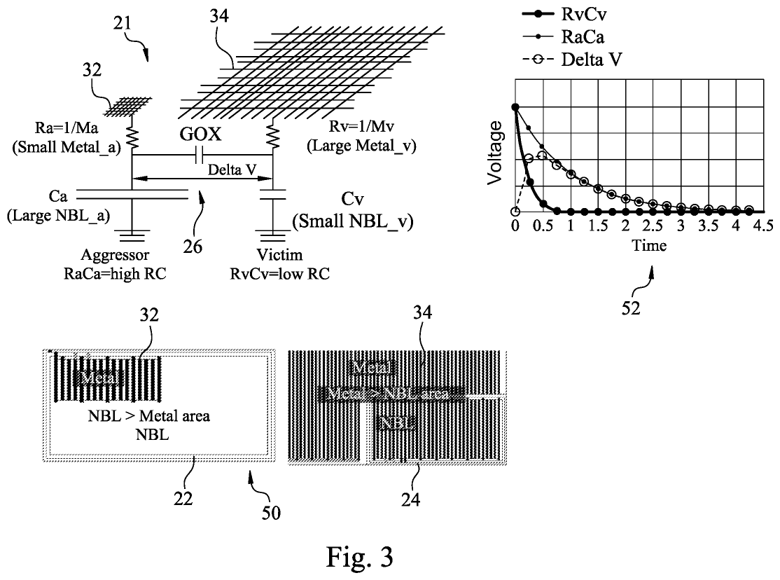

Hence, the asymmetry of the aggressor versus victim RC time constants can be obtained by having asymmetrical metal areas Mₐ versus Mᵥ, by having asymmetrical isolation well areas NBLₐ area versus NBLᵥ area, or a combination thereof. As diagrammatically indicated in FIG. 1, part (C), this example employs Mₐ>>Mᵥ and Cₐ<<Cᵥ so that RₐCₐ<<RᵥCᵥ. This is the case also for the examples of FIGS. 2 and 4-7 to be described. Alternatively, if Mₐ<<Mᵥ and Cₐ>>Cᵥ then RₐCₐ>>RᵥCᵥ. This is the case for the examples of FIGS. 3 and 8-11 to be described.

In general, process electrical charge can be monitored by the process charge detection circuit 20 of FIG. 1, part (C) as follows. Process charge developing on the aggressor antenna 32 can discharge through the connection of the aggressor antenna 32 to the victim isolation well 24 via the gate oxide 26. Denoting the gate oxide capacitance as Cₒₓ, electrical current Iₒₓ flowing through the gate oxide 26 is

$${I}_{o x} = {C}_{o x} \frac{d {V}_{o x}}{d t}$$

where Vₒₓ is the voltage across the gate oxide 26. Hence, by monitoring the voltage Vₒₓ using a voltmeter 36, the discharge of process charge on the aggressor antenna 32 can be detected and quantitatively measured. Additionally, process charge developing in the aggressor isolation well 22 can discharge through the connection of the aggressor isolation well 22 to the victim isolation well 24 via the gate oxide 26. Hence, monitoring the voltage Vₒₓ using a voltmeter 36 also enables the discharge of process charge in the aggressor isolation well 22 to be detected and quantitatively measured. Consequently, the process charge detection circuit 20 of FIG. 1, part (C) advantageously can detect and quantitatively measure static electrical charge accumulated on patterned metal layers during BEOL processing (by way of the aggressor antenna 32 as just described) and also can detect and quantitatively measure static electrical charge accumulated in the isolation wells during FEOL and/or BEOL processing (by way of the aggressor well 22 as just described. The ability to detect both charge potentially causing PID accumulating on the metal and in wells makes the disclosed process charge detection circuit 20 more versatile than process charge detection circuits that can only detect static electrical charge accumulated on patterned metal layers.

In the embodiment of FIG. 1, part (C), the voltage across the gate oxide 26 is measured by the diagrammatically indicated voltmeter 36. In the illustrative embodiments, the gate oxide 26 is the gate oxide of an FET (e.g., a planar FET, FinFET, or GAA-FET, for example), and the voltmeter 36 can include or incorporate the FET into the voltage measuring apparatus. The voltmeter 36 may include other components such as an analog-to-digital converter (ADC), peak detector, or so forth, and may be fabricated into the semiconductor wafer 10, optionally as part of the IC 12. Alternatively, the voltmeter 36 may be a separate component coupled to (the remainder of) the process charge detection circuit 20 by way of contact pads formed on the wafer 10. Moreover, while the illustrative example measures the voltage across the gate oxide 26, in other embodiments another electrical parameter of the gate oxide 26 may be measured, such as the electrical current through the gate oxide 26 measured using an ammeter.

With reference now to FIG. 2, the layout and operation of the process charge detection circuit 20 of FIG. 1, part (C) is further described. The bottom portion of FIG. 2 diagrammatically shows a layout 40 of the process charge detection circuit 20 showing the larger area aggressor antenna 32 which is larger than the area of the aggressor isolation well 22, and the smaller area victim antenna 34 which is smaller than the area of the victim isolation well 24. This results in RₐCₐ being low and RᵥCᵥ being high. In the upper left of FIG. 2, a graph 42 plots the time constants RₐCₐ and RᵥCᵥ, along with the voltage across the gate oxide 26 during discharge of process electrical charge. The voltage across the gate oxide 26 is denoted in FIG. 2 as “Delta V”. The difference in RC time constants provides for a gradual release of the process charge, as seen in the graph 42. In some embodiments, the metal area Mₐ of the aggressor antenna 32 is at least four times larger than the NBLₐ area of the aggressor isolation well 22 and the NBLᵥ area of the victim isolation well 24 is at least four times larger than the metal area Mᵥ of the victim antenna 34, in order to ensure a sizable asymmetry (i.e., to ensure RᵥCᵥ>>RₐCₐ).

With reference now to FIG. 3, the layout and operation of another embodiment of the process charge detection circuit 21 is described. In this embodiment, the area Mᵥ of the victim antenna 34 is larger than the metal area Mₐ of the aggressor antenna 32, and the NBLₐ area of the aggressor isolation well 22 is larger than the NBLᵥ area of the victim isolation well 24, as shown in the layout 50 of FIG. 3. This results in RₐCₐ being high and RᵥCᵥ being low. In the upper left of FIG. 2, a graph 52 plots the time constants RₐCₐ and RᵥCᵥ, along with the voltage across the gate oxide 26 during discharge of process electrical charge. The voltage across the gate oxide 26 is again denoted in FIG. 3 as “Delta V”. The difference in RC time constants again provides for a gradual release of the process charge, as seen in the graph 52. In some embodiments, the NBLₐ area of the aggressor isolation well 22 is at least four times larger than the metal area Mₐ of the aggressor antenna 32 and the metal area Mᵥ of the victim antenna 34 is at least four times larger than the NBLᵥ area of the victim isolation well 24 (i.e., to ensure RₐCₐ>>RᵥCᵥ).

With brief reference back to FIG. 1, it will be appreciated that the process charge detection circuit 21 of FIG. 3 could be substituted for the process charge detection circuit 20 of FIG. 2 in the overall IC structure of FIG. 1.

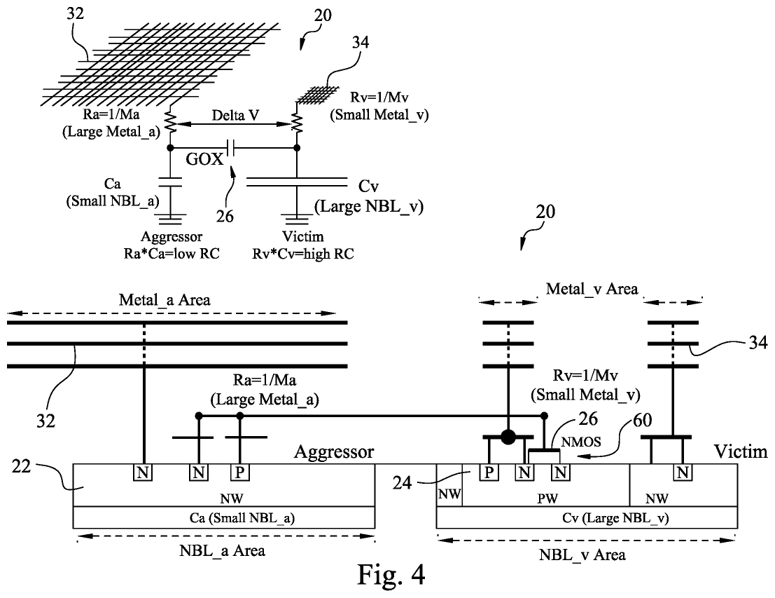

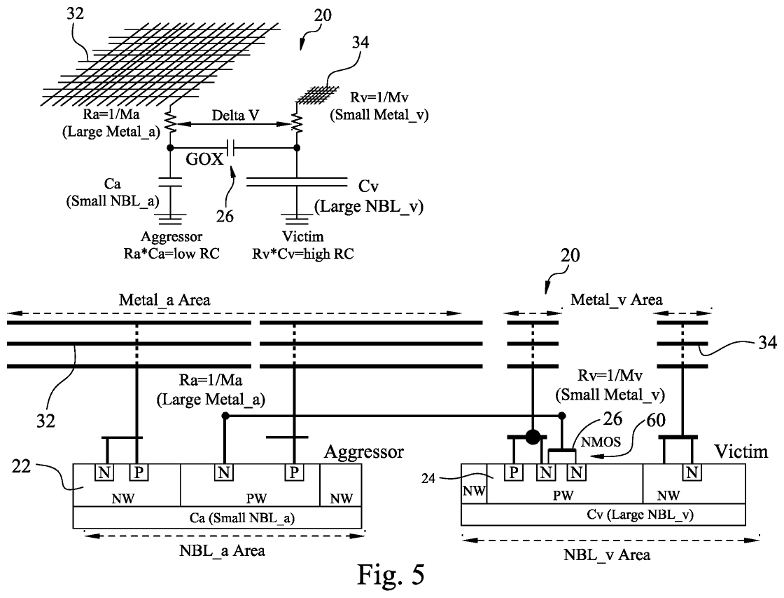

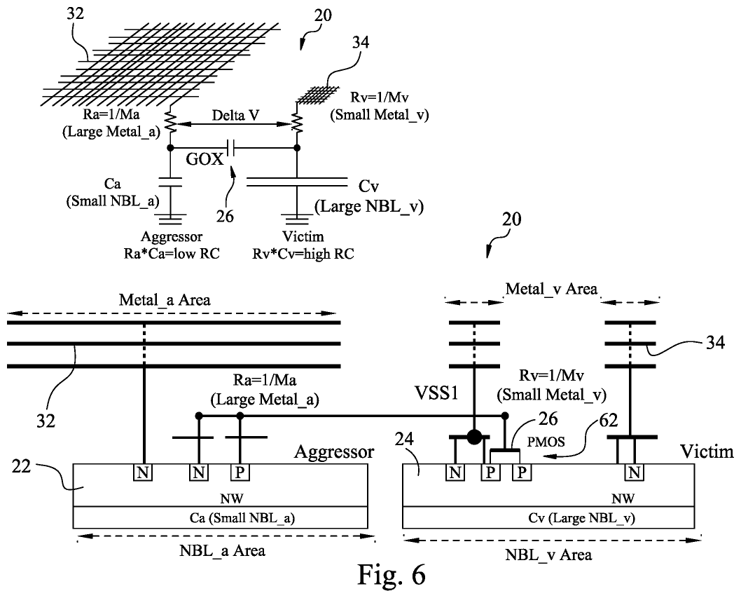

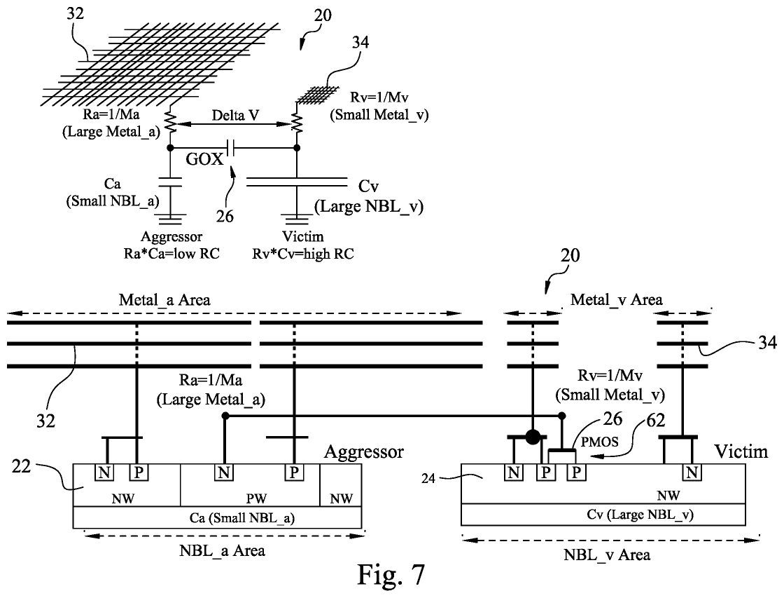

With reference now to FIGS. 4-7, several nonlimiting illustrative embodiments of the process charge detection circuit 20 of FIG. 2 in which RᵥCᵥ>>RₐCₐ are described. In each of FIGS. 4-7, the process charge detection circuit 20 is shown as an equivalent circuit (upper drawing) and as a diagrammatic side-sectional view of the process charge detection circuit 20 (bottom drawing). FIGS. 4 and 5 illustrate two embodiments of the process charge detection circuit 20 in which the gate oxide 26 disposed on or in the victim isolation well 24 is the gate oxide of an n-channel FET (i.e. NMOS device) 60 disposed on or in the victim isolation well 24. The NMOS device 60 may, for example, be a planar NMOS formed in the victim isolation well 24, or an n-channel FinFET or GAA-FET formed on the victim isolation well 24. FIGS. 6 and 7 illustrate two embodiments of the process charge detection circuit 20 in which the gate oxide 26 disposed on or in the victim isolation well 24 is the gate oxide of a p-channel FET (i.e. PMOS device) 62 disposed on or in the victim isolation well 24. The PMOS device 62 may, for example, be a planar PMOS formed in the victim isolation well 24, or a p-channel FinFET or GAA-FET formed on the victim isolation well 24. In some more limiting implementations of each of the embodiments of FIGS. 4-7, the metal area Mₐ of the aggressor antenna 32 is at least four times larger than the NBLₐ area of the aggressor isolation well 22 and the NBLᵥ area of the victim isolation well 24 is at least four times larger than the metal area Mᵥ of the victim antenna 34, in order to ensure a sizable asymmetry (i.e., to ensure RᵥCᵥ>>RₐCₐ).

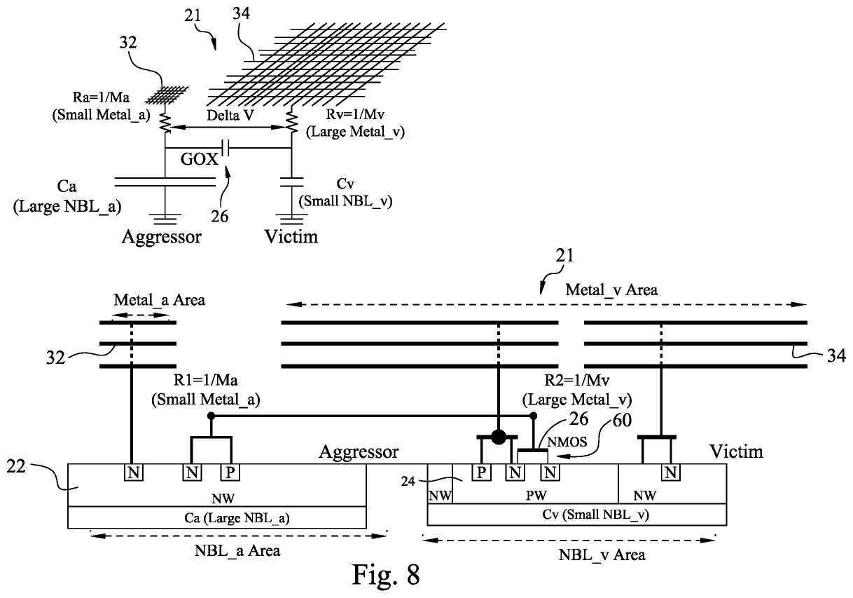

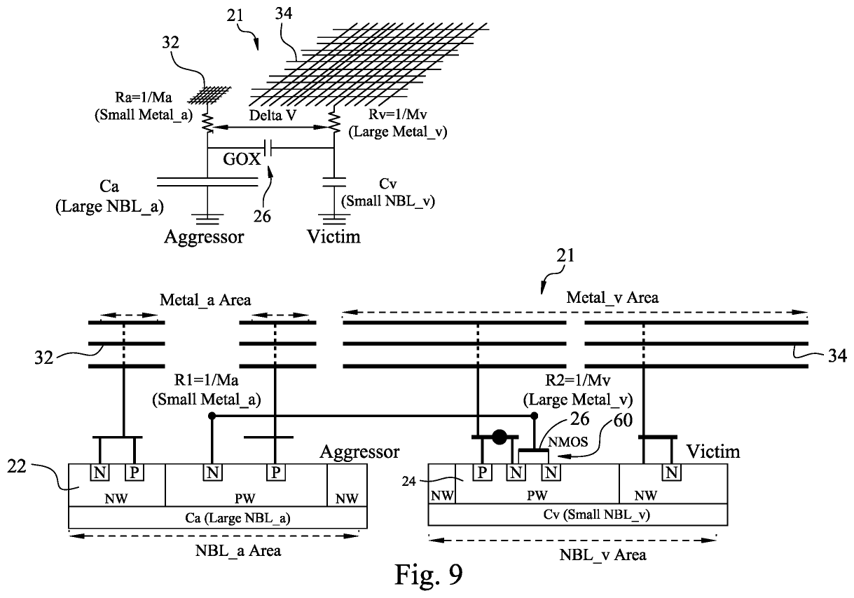

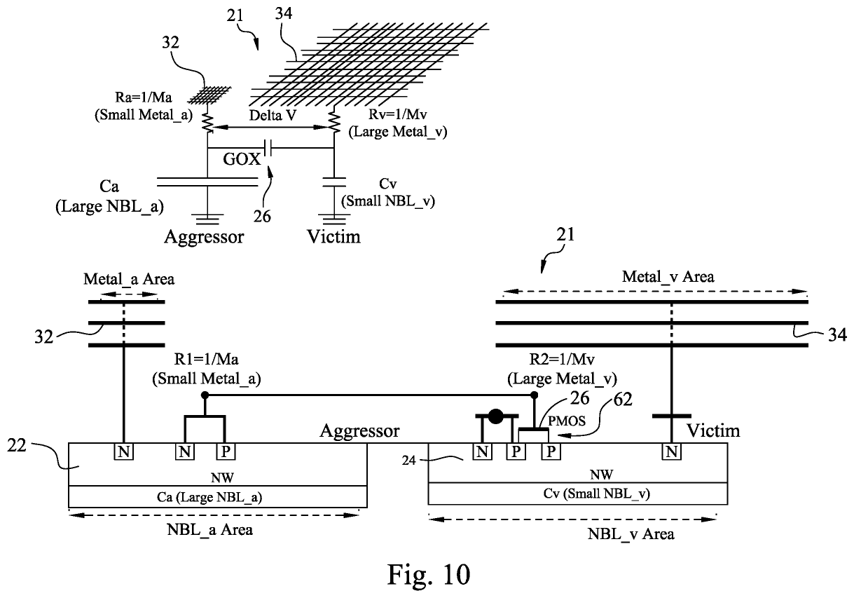

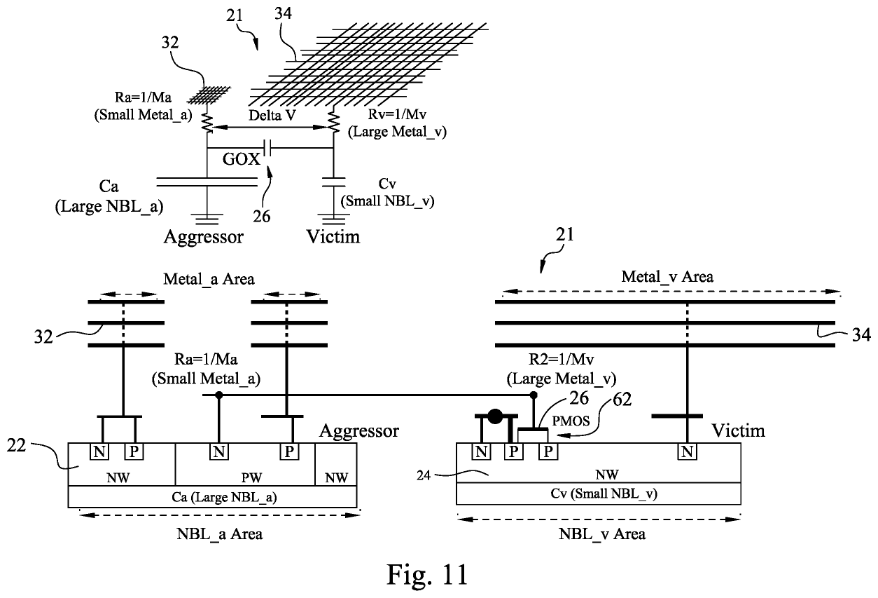

With reference now to FIGS. 8-11, several nonlimiting illustrative embodiments of the process charge detection circuit 21 of FIG. 2 in which RₐCₐ>>RᵥCᵥ are described. In each of FIGS. 8-11, the process charge detection circuit 21 is shown as an equivalent circuit (upper drawing) and as a diagrammatic side-sectional view of the process charge detection circuit 21 (bottom drawing). FIGS. 8 and 9 illustrate two embodiments of the process charge detection circuit 21 in which the gate oxide 26 disposed on or in the victim isolation well 24 is the gate oxide of an n-channel FET (i.e. NMOS device) 60 disposed on or in the victim isolation well 24. The NMOS device 60 may, for example, be a planar NMOS formed in the victim isolation well 24, or an n-channel FinFET or GAA-FET formed on the victim isolation well 24. FIGS. 10 and 11 illustrate two embodiments of the process charge detection circuit 21 in which the gate oxide 26 disposed on or in the victim isolation well 24 is the gate oxide of a p-channel FET (i.e. PMOS device) 62 disposed on or in the victim isolation well 24. The PMOS device 62 may, for example, be a planar PMOS formed in the victim isolation well 24, or a p-channel FinFET or GAA-FET formed on the victim isolation well 24. In some more limiting implementations of each of the embodiments of FIGS. 8-11, the NBLₐ area of the aggressor isolation well 22 is at least four times larger than the metal area Mₐ of the aggressor antenna 32 and the metal area Mᵥ of the victim antenna 34 is at least four times larger than the NBLᵥ area of the victim isolation well 24 (i.e., to ensure RₐCₐ>>RᵥCᵥ).

With reference back to FIGS. 4-11, some embodiments of the process charge detection circuit 20 or 21 include diodes in the aggressor and/or victim isolation wells 22, 24. For example, the embodiments of FIGS. 5, 7, 9, and 11 include at least one diode in the aggressor isolation well 22, while the embodiments of FIGS. 4, 5, 8, and 9 include at least one diode in the victim isolation well 24.

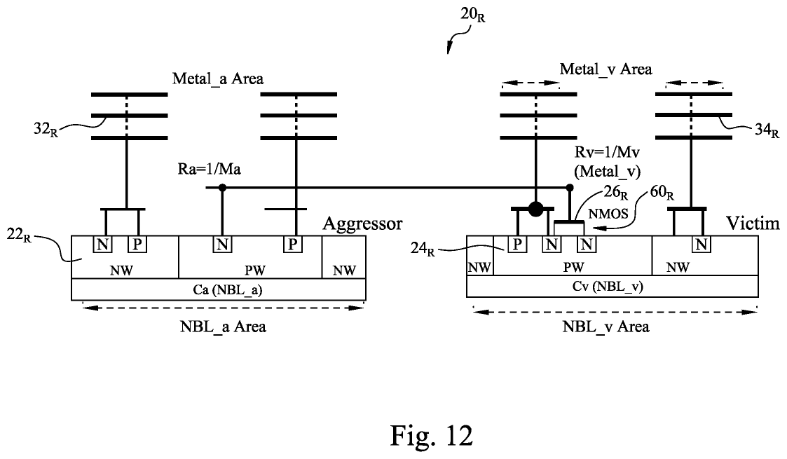

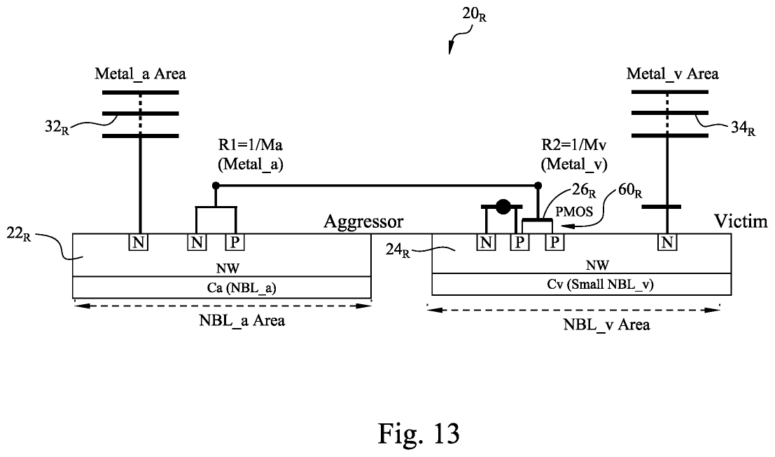

With reference to FIGS. 12 and 13, in some embodiments a reference circuit 20_{R} or reference circuit 21_{R} is provided, which is similar to the process charge detection circuit 20 or to process charge detection circuit 21, respectively, except that it is symmetric, i.e. RₐCₐ=RᵥCᵥ. As shown in FIGS. 12 and 13, the reference circuit 20_{R} or reference circuit 21_{R} includes a first (i.e. aggressor) reference isolation well 22_{R}, a reference gate oxide 26_{R} disposed on or in the first (i.e. aggressor) reference isolation well 22_{R}, a second (i.e. victim) reference isolation well 24_{R} electrically connected with the first (i.e. aggressor) reference isolation well 22_{R} via the reference gate oxide 26_{R}, a first (i.e. aggressor) reference antenna 32_{R} electrically connected with the first (i.e. aggressor) reference isolation well 22_{R} and together with the first (i.e. aggressor) reference isolation well 22_{R} defining a first reference RC time constant RₐCₐ, and a second (i.e. victim) reference antenna 34_{R} electrically connected with the second (i.e. victim) reference isolation well 24_{R} and together with the second (i.e. victim) reference isolation well 24_{R} defining a second reference RC time constant RᵥCᵥ. In the reference circuits 20, 21 of FIGS. 12 and 13, the aggressor RC time constant RₐCₐ is equal to the victim RC time constant RᵥCᵥ.

In the reference circuit 20 of FIG. 12, the gate oxide 26_{R} disposed on or in the victim reference isolation well 24_{R} is the gate oxide of a reference n-channel FET (i.e. NMOS device) 60_{R} disposed on or in the victim reference isolation well 24_{R}. The reference NMOS device 60_{R} may, for example, be a planar NMOS formed in the victim reference isolation well 24_{R}, or an n-channel FinFET or GAA-FET formed on the victim reference isolation well 24_{R}.

In the reference circuit 21 of FIG. 13, the gate oxide 26_{R} disposed on or in the victim reference isolation well 24_{R} is the gate oxide of a reference p-channel FET (i.e. PMOS device) 62_{R} disposed on or in the victim reference isolation well 24_{R}. The reference PMOS device 62_{R} may, for example, be a planar NMOS formed in the victim reference isolation well 24_{R}, or an n-channel FinFET or GAA-FET formed on the victim reference isolation well 24_{R}.

Using the reference circuit 20 or reference circuit 21 in conjunction with the process charge detection circuit 20 or the process charge detection circuit 21 advantageously provides greater precision in quantitatively assessing the process electrical charge. To do so, the detecting of the process electrical charge further comprises measuring a voltage across (or other electrical parameter) of the reference gate oxide 26_{R} and comparing the measured electrical parameter of the gate oxide 26 of the process charge detection circuit 20 or 21 and the measured electrical parameter of the reference gate oxide 26_{R}.

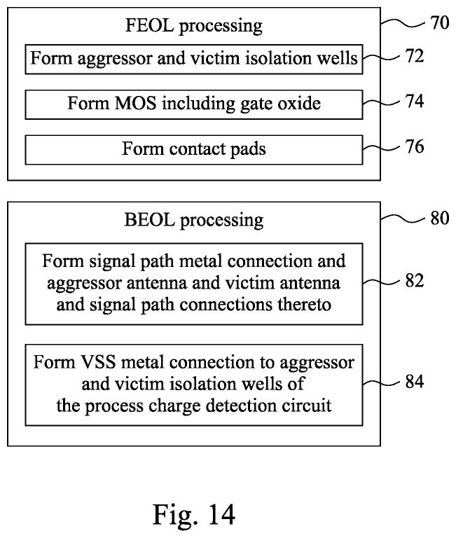

With reference to FIG. 14, a method of manufacturing the process charge detection circuit 20 or 21 is described. During FEOL processing 70 of the IC fabrication process for forming the IC die 12 (see FIG. 1), the aggressor and victim isolation wells 22, 24 are formed in an operation 72. This can optionally be done in parallel with formation of similar isolation wells for functional circuit components formed in the device area 14 (see FIG. 1). For example, the processing 72 may include forming NBL and STI regions using ion implantation to define both the isolation wells 22, 24 of the process charge detection circuit 20 or 21 and to define isolation of functional circuit components. In an operation 74 the NMOS 60 or PMOS 62 is formed in the victim isolation well 24. Again, operation 74 can optionally be performed concurrently with FET formation operations used to form circuit component FETs in the device area 14. In some such embodiments, the NMOS 60 or PMOS 62 is of the same type as the FETs of the device area 14, e.g. if the IC 12 employs GAA-FET devices as circuit components in the device area 14 then the NMOS 60 or PMOS 62 is suitably also a GAA-FET formed concurrently with the GAA-FETs in the device area 14. Additionally, the operation 74 forms diodes in those embodiments in one or both isolation wells 22, 24 of the process charge detection circuit 20 or 21 includes at least one diode. In an operation 76, electrical contacts are formed to the isolation wells 22, 24. Again, this can optionally be performed in parallel with formation of electrical contacts to functional circuit components in the device area 14.

After the FEOL processing 70 is complete, BEOL processing 80 is performed to interconnect the circuit components in the device area 14 to complete fabrication of the IC 12. As part of the BEOL processing 80, in an operation 82 the signal path metal connection is made which connects the aggressor isolation region 22 to the victim isolation region 24 via the gate oxide 26, and the aggressor and victim antennae 32, 34 are formed along with signal paths connecting the aggressor and victim antennae 32, 34 with the isolation regions 22, 24. In an operation 84, the V_{SS} metal connections are made to the isolation wells 22, 24 of the process charge detection circuit 20 or 21. Yet again, the operation 84 can be performed concurrently with V_{SS} metal connection to circuit components in the device area 14.

In the following, some additional illustrative embodiments are disclosed.

In some illustrative embodiments, a method of detecting or monitoring process electrical charge produced during fabrication of an IC on a semiconductor wafer is disclosed. The method includes fabricating a process charge detection circuit on or in the semiconductor wafer. The process charge detection circuit includes a victim isolation well, a gate oxide disposed on or in the victim isolation well, an aggressor isolation well electrically connected with the victim isolation well via the gate oxide, a victim antenna electrically connected with the victim isolation well and together with the victim isolation well defining a victim RC time constant RᵥCᵥ, and an aggressor antenna electrically connected with the aggressor isolation well and together with the aggressor isolation well defining an aggressor RC time constant RₐCₐ that is different from RᵥCᵥ. The method further includes detecting process charge using the process charge detection circuit. The detecting comprises measuring an electrical parameter of the gate oxide.

In some illustrative embodiments, a process charge detection circuit disposed on or in a semiconductor wafer on which an IC is fabricated. The process charge detection circuit includes: a second isolation well; a FET including a gate oxide disposed on or in the second isolation well; a first isolation well electrically connected with the second isolation well via the gate oxide; a second antenna electrically connected with the second isolation well and together with the second isolation well defining a second RC time constant; and a first antenna electrically connected with the first isolation well and together with the first isolation well defining a first RC time constant. The first RC time constant is at least eight times larger than the second RC time constant or the second RC time constant is at least eight times larger than the first RC time constant.

In some illustrative embodiments, a method of detecting or monitoring process electrical charge produced during fabrication of an IC on a semiconductor wafer is disclosed. The method includes fabricating a process charge detection circuit on or in the semiconductor wafer. The process charge detection circuit includes: a second isolation well, an FET including a gate oxide disposed on or in the second isolation well, a first isolation well electrically connected with the second isolation well via the gate oxide, a second antenna electrically connected with the second isolation well and together with the second isolation well defining a second RC time constant, and a first antenna electrically connected with the first isolation well and together with the first isolation well defining a first RC time constant. The method further includes detecting process charge using the process charge detection circuit. The detecting comprises measuring an electrical parameter of the gate oxide. In the process charge detection circuit, one of: (i) a metal area of the first antenna is at least four times larger than an area of the first isolation well and an area of the second isolation well is at least four times larger than a metal area of the second antenna, or (ii) an area of the first isolation well is at least four times larger than a metal area of the first antenna and a metal area of the second antenna is at least four times larger than an area of the second isolation well.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of detecting or monitoring process electrical charge produced during fabrication of an integrated circuit (IC) on a semiconductor wafer, the method comprising:
fabricating a process charge detection circuit on or in the semiconductor wafer, the process charge detection circuit including:
a victim isolation well,
a gate oxide disposed on or in the victim isolation well,
an aggressor isolation well electrically connected with the victim isolation well via the gate oxide,
a victim antenna electrically connected with the victim isolation well and together with the victim isolation well defining a victim RC time constant RᵥCᵥ, and
an aggressor antenna electrically connected with the aggressor isolation well and together with the aggressor isolation well defining an aggressor RC time constant RₐCₐ that is different from RᵥCᵥ; and
detecting process charge using the process charge detection circuit wherein the detecting comprises measuring an electrical parameter of the gate oxide.

2. The method of claim 1 wherein the process charge detection circuit further comprises an NMOS device including said gate oxide or a PMOS device including said gate oxide.

3. The method of claim 1 wherein the electrical parameter of the gate oxide comprises a voltage across the gate oxide.

4. The method of claim 1 wherein the victim isolation well comprises an n-type buried layer (NBL) or a deep n-type well (DNW), and the aggressor isolation well comprises an NBL or a DNW.

5. The method of claim 1 wherein one of:
RₐCₐ is at least eight times larger than RᵥCᵥ or
RᵥCᵥ is at least eight times larger than RₐCₐ.

6. The method of claim 1 wherein:
a metal area of the aggressor antenna is at least four times larger than an area of the aggressor isolation well; and
an area of the victim isolation well is at least four times larger than a metal area of the victim antenna.

7. The method of claim 1 wherein:
an area of the aggressor isolation well is at least four times larger than a metal area of the aggressor antenna; and
a metal area of the victim antenna is at least four times larger than an area of the victim isolation well.

8. The method of claim 1 further comprising:
fabricating a reference circuit on or in the semiconductor wafer, the reference circuit including:
a first reference isolation well,
a reference gate oxide disposed on or in the first reference isolation well,
a second reference isolation well electrically connected with the first reference isolation well via the reference gate oxide,
a first reference antenna electrically connected with the first reference isolation well and together with the first reference isolation well defining a first reference RC time constant, and
a second reference antenna electrically connected with the second reference isolation well and together with the second reference isolation well defining a second reference RC time constant that is equal to the first reference RC time constant;
wherein the detecting further comprises measuring an electrical parameter of the reference gate oxide and comparing the measured electrical parameter of the gate oxide and the measured electrical parameter of the reference gate oxide.

9. The method of claim 1 wherein the fabrication of the IC includes front end-of-line (FEOL) processing followed by back end-of-line (BEOL) processing and wherein the fabricating a process charge detection circuit includes:
fabricating the victim isolation well, the aggressor isolation well, and the gate oxide disposed on or in the victim isolation well during the FEOL processing; and
fabricating the aggressor antenna and the victim antenna during the BEOL processing.

10. The method of claim 1 wherein the fabrication of the IC introduces process electrical charge comprising isolation well charging, and the detecting of process charge includes:
detecting the isolation well charging by detecting an electrical discharge between the aggressor isolation well and the victim isolation well through the gate oxide by the measuring of the electrical parameter of the gate oxide.

11. The method of claim 1 wherein the process charge detection circuit is fabricated on or in the semiconductor wafer at a location relative to the IC which is outside of a seal ring of the IC or inside a die area of the IC.

12. A process charge detection circuit disposed on or in a semiconductor wafer on which an integrated circuit (IC) is fabricated, the process charge detection circuit comprising:
a second isolation well;
a field-effect transistor (FET) including a gate oxide disposed on or in the second isolation well;
a first isolation well electrically connected with the second isolation well via the gate oxide;
a second antenna electrically connected with the second isolation well and together with the second isolation well defining a second RC time constant; and
a first antenna electrically connected with the first isolation well and together with the first isolation well defining a first RC time constant;
wherein the first RC time constant is at least eight times larger than the second RC time constant or the second RC time constant is at least eight times larger than the first RC time constant.

13. The process charge detection circuit of claim 12 wherein the second isolation well comprises an n-type buried layer (NBL) or a deep n-type well (DNW), and the first isolation well comprises an NBL or a DNW.

14. The process charge detection circuit of claim 12 wherein:
a metal area of the first antenna is at least four times larger than an area of the first isolation well; and
an area of the second isolation well is at least four times larger than a metal area of the second antenna.

15. The process charge detection circuit of claim 12 wherein:
an area of the first isolation well is at least four times larger than a metal area of the first antenna; and
a metal area of the second antenna is at least four times larger than an area of the second isolation well.

16. The process charge detection circuit of claim 12 further comprising:
a reference circuit disposed on or in the semiconductor wafer, the reference circuit including:
a second reference isolation well;
a reference FET including a reference gate oxide disposed on or in the second reference isolation well;
a first reference isolation well electrically connected with the second reference isolation well via the reference gate oxide;
a second reference antenna electrically connected with the second reference isolation well and together with the second reference isolation well defining a second reference RC time constant; and
a first reference antenna electrically connected with the first reference isolation well and together with the first reference isolation well defining a first reference RC time constant that is equal to the second reference RC time constant.

17. The process charge detection circuit of claim 12 wherein the process charge detection circuit is fabricated on or in the semiconductor wafer at a location relative to the IC which is outside of a seal ring of the IC or inside a die area of the IC.

18. A method of detecting or monitoring process electrical charge produced during fabrication of an integrated circuit (IC) on a semiconductor wafer, the method comprising:
fabricating a process charge detection circuit on or in the semiconductor wafer, the process charge detection circuit including:
a second isolation well,
a field effect transistor (FET) including a gate oxide disposed on or in the second isolation well,
a first isolation well electrically connected with the second isolation well via the gate oxide,
a second antenna electrically connected with the second isolation well and together with the second isolation well defining a second RC time constant, and
a first antenna electrically connected with the first isolation well and together with the first isolation well defining a first RC time constant; and
detecting process charge using the process charge detection circuit wherein the detecting comprises measuring an electrical parameter of the gate oxide;
wherein one of:
a metal area of the first antenna is at least four times larger than an area of the first isolation well and an area of the second isolation well is at least four times larger than a metal area of the second antenna, or
an area of the first isolation well is at least four times larger than a metal area of the first antenna and a metal area of the second antenna is at least four times larger than an area of the second isolation well.

19. The method of claim 18 further comprising:
fabricating a reference circuit on or in the semiconductor wafer, the reference circuit including:
a first reference isolation well,
a reference gate oxide disposed on or in the first reference isolation well,
a second reference isolation well electrically connected with the first reference isolation well via the reference gate oxide,
a first reference antenna electrically connected with the first reference isolation well and together with the first reference isolation well defining a first reference RC time constant, and
a second reference antenna electrically connected with the second reference isolation well and together with the second reference isolation well defining a second reference RC time constant that is equal to the first reference RC time constant;
wherein the detecting further comprises measuring an electrical parameter of the reference gate oxide and comparing the measured electrical parameter of the gate oxide and the measured electrical parameter of the reference gate oxide.

20. The method of claim 18 wherein the fabrication of the IC introduces process electrical charge comprising isolation well charging, and the detecting of process charge includes:
detecting the isolation well charging by detecting an electrical discharge between the first isolation well and the second isolation well through the gate oxide by the measuring of the electrical parameter of the gate oxide.
